(19) United States
(12) Patent Application Publication
(10) Pub. No.: US 2013/0005118 A1
(43) Pub. Date: Jan. 3, 2013

(54) FORMATION OF III-V MATERIALS USING MOCVD WITH CHLORINE CLEANS OPERATIONS

(76) Inventors: Sung Won Jun, Cupertino, CA (US); Yan Wang, Sunnyvale, CA (US); Hua Chung, San Jose, CA (US); Jiang Lu, Milpitas, CA (US); Kuan Chien Keris Shen, Santa Clara, CA (US); Shiva Rai, Champaign, IL (US)

(21) Appl. No.: 13/535,845

(22) Filed: Jun. 28, 2012

Related U.S. Application Data
(60) Provisional application No. 61/503,909, filed on Jul. 1, 2011.

(51) Int. Cl. H01L 21/205

(52) U.S. Cl. 438/478; 257/E21.112

(57) ABSTRACT

Methods of forming III-V materials using metal organic chemical vapor deposition (MOCVD) with chlorine cleans operations are described. A chlorine-clean operation may further season an MOCVD process for improved throughput for high volume manufacturing.

### CROSS-REFERENCE TO RELATED APPLICATIONS

This application claims the benefit of U.S. Provisional Application No. 61/503,909, filed Jul. 1, 2011, the entire contents of which are hereby incorporated by reference herein.

### BACKGROUND

1) Field

Embodiments of the present invention pertain to the field of group III-V materials and, in particular, to the formation of III-V materials using metal organic chemical vapor deposition (MOCVD) with chlorine cleans operations.

2) Description of Related Art

Group III-V materials are playing an ever increasing role in the semiconductor and related, e.g. light-emitting diode (LED), industries. Often, group III-V materials are difficult to grow or deposit without the formation of defects or cracks. For example, high quality surface preservation of select films, e.g. a gallium nitride film, is not straightforward in many applications using stacks of material layers fabricated sequentially.

### SUMMARY

Embodiments of the present invention include methods of forming III-V materials using metal organic chemical vapor deposition (MOCVD) with chlorine cleans operations.

In an embodiment, a method of fabricating a III-V material layer includes cleaning an MOCVD chamber with a chlorine-clean process. Subsequently, a silicon substrate is moved into the MOCVD chamber. A gallium nitride (GaN) layer is then formed directly on the silicon substrate in the MOCVD chamber.

In another embodiment, a method of fabricating a III-V material layer includes cleaning an MOCVD chamber with a plurality of chlorine-clean cycles. Subsequently, a silicon substrate is moved into the MOCVD chamber. An aluminum nitride (AlN) layer is then formed directly on the silicon substrate in the MOCVD chamber.

### BRIEF DESCRIPTION OF THE DRAWINGS

FIG. 1 includes a plot of XRD data taken throughout a number of AlN deposition runs, in accordance with an embodiment of the present invention.

FIG. 2 includes AlN (002) FWHM plots for AlN-only versus AlN and Cl₂ clean cycles, respectively, in accordance with an embodiment of the present invention.

FIG. 3 is a plot of XRD measurements of GaN (002), GaN (102), and AlN (002) films, in accordance with an embodiment of the present invention.

FIG. 4 is a schematic cross-sectional view of an MOCVD chamber suitable for use in forming III-V materials using MOCVD with chlorine cleans operations, in accordance with an embodiment of the present invention.

FIG. 5 illustrates a system suitable for use in forming III-V materials using MOCVD with chlorine cleans operations, in accordance with an embodiment of the present invention.

FIG. 6 illustrates a cross-sectional view of a gallium nitride (GaN)-based light-emitting diode (LED), in accordance with an embodiment of the present invention.

FIG. 7 illustrates a cluster tool schematic, an LED structure, and a time-to-deposition plot, in accordance with one or more embodiments of the present invention.

### DETAILED DESCRIPTION

Methods of forming III-V materials using metal organic chemical vapor deposition (MOCVD) with chlorine cleans operations are described. In the following description, numerous specific details are set forth, such as MOCVD chamber configurations and material regimes, in order to provide a thorough understanding of embodiments of the present invention. It will be apparent to one skilled in the art that embodiments of the present invention may be practiced without these specific details. In other instances, well-known features, such as tool layouts or specific diode configurations, are not described in detail in order to not unnecessarily obscure embodiments of the present invention. Furthermore, it is to be understood that the various embodiments shown in the Figures are illustrative representations and are not necessarily drawn to scale. Additionally, other arrangements and configurations may not be explicitly disclosed in embodiments herein, but are still considered to be within the spirit and scope of the invention.

In a first aspect of the present invention, processes for gallium nitride (GaN) epitaxial growth on silicon substrates using metal organic chemical vapor deposition (MOCVD) with chamber cleaning are described. MOCVD has been widely adopted for growing group III-V compound semiconductor epilayers. For example, MOCVD techniques have been used to successfully grow GaN, aluminum nitride (AlN), AlxGa(1-x)N, or InxGa(1-x)N crystals for fabricating optical and electronic devices, such as light emitting diode (LEDs) and high electron mobility transistors (HEMTs), etc. Most typically, GaN growth is performed on sapphire or SiC substrates, which are expensive and not necessarily available in large-scale formats such as 12 inch wafers. As such, there is an incentive for developing a process of growing GaN on silicon substrates in order to reduce substrate cost. Furthermore, due to the maturity of processes already widely performed on silicon-based integrated circuits (ICs), an ability to grow GaN on silicon may facilitate ultimate integration of LEDs or HEMTs devices with integrated circuits. However, challenges remain for growing high quality GaN on silicon due to high mismatches of lattice parameters and thermal coefficients. Film cracking may be a particular issue with GaN growth on silicon.

MOCVD processes typically include thermal break-down of molecular precursor components to form highly structured single-crystal layers on a receiving substrate or other layer surface. Because of the highly reactive nature of such precursor components, gas phase reaction often occurs away from the substrate or other layer receiving surface. Remnants, residues, or products from the gas phase reactions that do not deposit on the receiving substrate or other layer receiving surface may undesirably deposit on the inner walls of an MOCVD reactor chamber, especially on the showerhead. The accumulation of such remnants, residues, or products may affect the chamber physical properties, and may lead to drift of the crystal growth environment. As such, MOCVD reaction chambers are typically routinely opened and manually cleaned of remnants, residues, or products deposited on portions of the chamber. The down time of the MOCVD chamber for manual cleaning can have a great impact on the productivity of the MOCVD tool.

In accordance with an embodiment of the present invention, a process for forming a film stack with a thicker than otherwise achievable GaN film grown on a silicon substrate is provided. The GaN film may have high crystal quality with no film cracking. In one such embodiment, chlorine (Cl₂) gas is used to clean an MOCVD chamber without opening the chamber. In a specific such embodiment, specifically tuned GaN growing conditions are used to reduce side reaction coating on the chamber inside walls. In an embodiment, the Cl2-based cleaning is a thermal chemical cleaning process.

In an embodiment, a stack of approximately 200 nanometers AlN layer, AlxGa(1-x)N layer(s) approximately in the range of 600-800 nanometers, and approximately 4 micron GaN film is grown on an approximately 1 millimeter thick silicon (111) substrate. However, other embodiments need not be limited to such dimensions, e.g., thinner silicon (111) substrates may be used. In one such embodiment, the relative Al concentration, x, is approximately in the range of 20% to 80%. In a specific such embodiment, the relative Al concentration, x, is approximately in the range of 60% to 80%.

In an embodiment, epitaxial films are processed at a relatively larger distance or gap from a showerhead in an MOCVD process as compared to conventional processing in the chamber. For example, in one embodiment, the epitaxial films are formed approximately 13 millimeters from the showerhead to reduce the coating on the showerhead surface from deposition of byproducts of gas phase reactions. However, in another embodiment, a standard spacing of approximately 10 millimeters is used. In an embodiment, the showerhead is pre-coated with Al₂O₃ particles or AlN particles to enable the showerhead surface to maintain a consistent emissivity regardless of byproduct coating on the surface of the showerhead.

In an embodiment, a low pressure MOCVD process is used to grow III-V films so that the gas phase reactions are reduced and chamber surface coating is minimized. More specifically, in one embodiment, AlN and AlGaN films are grown at less than approximately 100 Torr, e.g., less than approximately 50 Torr, while a GaN film is grown at less than approximately 300 Torr. In an embodiment, a higher temperature MOCVD process is used to enhance clean performance in the MOCVD chamber. For example, in one embodiment, AlN is grown at wafer temperatures greater than approximately 1100 degrees Celsius and, in a specific embodiment, with a relatively low V/III ratio of less than approximately 2500. In another such embodiment, AlGaN and GaN are grown at temperatures of greater than 1020 degrees Celsius and, in a specific embodiment, with a V/III ratio less than approximately 2000.

In an embodiment, III-V material stack growth sequence includes hydrogen (H₂) baking at a temperature greater than or equal to approximately 1040 degrees Celsius. For example, in one such embodiment, an H₂ bake is performed, followed directly by AlN growth, AlGaN growth, and GaN growth processes. Such an H₂ bake may be used for pre-treating the surface of a silicon wafer. However, in other embodiment, it may not be necessary to chemically pre-treat the silicon wafer.

In an embodiment, a dirty carrier used to support a substrate is cleaned together with an MOCVD chamber following each III-V material layer deposition process. In one such embodiment, a carrier cleaning process is run with a larger carrier-showerhead spacing of approximately 25 millimeters at a temperature greater than or equal to approximately 700 degrees Celsius. In a specific embodiment, Cl2 is used to clean the carrier and to minimize the contamination of showerhead surface. In an embodiment, after the carrier is cleaned, the same carrier can be used to clean the showerhead surface, during which the clean carrier is brought into close proximity to the showerhead, e.g., within approximately 10 millimeters. In one such embodiment, a heat exchanger and lamp power is adjusted so that the showerhead surface is maintained at a temperature greater than or equal to approximately 150 degrees Celsius. However, in an alternative embodiment, a temperature of approximately 80 degrees Celsius is used, which is closer to typical processing conditions.

In an embodiment, a chamber cleaning process is performed at a pressure of approximately 50 Torr or less with a Cl₂ flow approximately in the range of 4-7 slm to clean a showerhead surface of an MOCVD chamber. In an embodiment where the residue deposited in the chamber is an Al rich nitride film, a periodic cycle process between approximately 50 Torr and 6 Torr is used. The Cl₂ of the clean may generate chlorides of the residue at higher chamber pressure, while and the low pressure portion of the cycle may be used to assist sublimation of formed AlCl₃. In an embodiment, processes described herein are used to fabricate a layer of GaN having a thickness greater than or equal to approximately 4 microns without cracking of the layer. In one specific such embodiment, the surface roughness (RMS) of the GaN layer is less than approximately 0.25 nanometers, and XRD is less than approximately 250 arc-sec (002) and less than approximately 450 arc-sec (102). In an embodiment, methods described herein stable processing without having to open an MOCVD chamber for manual cleaning.

In a second aspect of the present invention, MOCVD chamber seasoning by a chlorine clean process is described. For example, in accordance with an embodiment of the present invention, recovery of AlN quality during high volume manufacturing on silicon substrates is achieved by use of a chlorine clean including MOCVD chamber seasoning.

GaN LED and power devices are receiving considerable attention. GaN growth on silicon substrates can melt the silicon due to Ga—Si eutectic formation even though the deposition temperature for GaN of 1020 degrees Celsius is less than the melting point of silicon, e.g., the eutectic formation may occur even as low as standard room temperature of approximately 25 degrees Celsius. The option to exchange GaN for AlN has been considered, but it may be difficult to grow AlN since temperatures greater than 1100 degrees Celsius are typically needed. Furthermore, AlN crystal quality must be maintained throughout a high volume manufacturing for high yields of high performance products, such as LEDs. For example, a first AlN deposition in an MOCVD chamber may be clean. However, subsequent AlN depositions performed in the same chamber may degrade. On the other hand, only performing a single chlorine clean operation prior to through-putting a number of AlN deposition runs may be insufficient for long term manufacturing quality.

In accordance with an embodiment of the present invention, more than one chlorine clean operation is run prior to, or during, a throughput of multiple wafers for AlN deposition in an MOCVD chamber. In one embodiment, a sufficient number of chlorine cleans operations is used to season the MOCVD chamber. The seasoning may involve a specific chamber chemical environment prepared by the loading of chlorine or chlorides formed there from in the MOCVD chamber. The chlorine or chlorides chemistry inside the chamber may aid in AlN nucleation by facilitating adatom movement.

As a comparative example, a conventional process may use a single chlorine clean process prior to approximately 15 runs of AlN deposition in an MOCVD chamber. However, the AlN depositions degrade with each of the 15 runs, possibly due to lack of seasoning in the MOCVD chamber. By contrast, in accordance with an embodiment of the present invention, at least one chlorine clean process is used per AlN deposition cycle. After several such dummy cycles, such as 2-6, the MOCVD chamber is seasoned for manufacturing runs. Each dummy cycle of AlN deposition may deposit approximately 200 nanometers of AlN. This approach may lead to formation of an appropriate amount of residual chlorine or chlorides (such as AlCl₃) in the MOCVD chamber to provide a seasoning benefit for subsequent manufacturing runs. In an embodiment, a H₂ bake is included in one or more of the Cl₂ cleaning cycles, but not necessarily in every cycle. The H₂ bake may be used to enhance sublimation of and to remove some of the chlorine or chloride from the MOCVD chamber, somewhat tempering the build-up of these species in the MOCVD chamber.

Thus, embodiments of the present invention may be used for the formation of group III nitrides on silicon substrates. For example, AlN may be used as an intermediate layer to enable growth of other nitrides (such as GaN) on silicon. As described above, due to eutectic formation of Ga and Si, Ga-containing nitrides may not be grown directly on a silicon substrate. Hence, high crystalline quality AlN may be used as an important layer in order to grow thick layers of Ga-containing nitrides thereon. In an embodiment, however, achieving repeatable high quality AlN includes proper chamber seasoning. The AlN layer itself may not be sufficient to season an MOCVD chamber. For example, the crystal quality by (002) XRD FWHM is maintained at approximately 3000 arcsec in the absence of a chlorine clean seasoning. In one embodiment, by introducing a chlorine clean, AlN layer crystal quality on (111) Si is improved and is demonstrated to show good repeatability. In addition, a chlorine clean may be responsible for good repeatability of GaN, AlGaN, and AlN on, e.g., 8 inch (111) silicon wafers in a single MOCVD chamber. Specifically, the addition of a chlorine clean may be an effective seasoning method to improve surface roughness as well as crystal quality of AlN films on 8 inch (111) silicon wafers.

In an embodiment, chamber seasoning processes are used to provide repeatable high quality AlN. In the absence of such chamber cleans, an AlN film formed on an 8 inch (111) silicon wafer may exhibit rough surface and poor crystal quality. A certain thickness of AlN films grown repeatedly, in conjunction with chlorine clean cycles, may be used to improve surface quality as well as crystal quality of an MOCVD-deposited AlN film. For example, in one embodiment, an AlN layer having a thickness of up to approximately 1 micron is formed through Cl₂ cleans/AlN depositions cycles, showing progressive improvement of AlN crystal quality. It is noted that deposition of an AlN layer itself, in the absence of Cl₂ clean cycles, may not be sufficient to season the MOCVD chamber.

In an embodiment, after proper chamber preventive maintenance, a 200 nanometer thick AlN layer is grown, and a chlorine clean is performed immediately thereafter. In one specific embodiment, approximately 5 such cycles are performed in an MOCVD chamber prior to using the chamber for high throughput manufacturing. In a specific such embodiment, an AlN layer formed in the MOCVD chamber following a number of Cl₂ cleans/AlN depositions cycles exhibits improved surface quality as well as crystal quality of the AlN layer. For example, a 5 micron by 5 micron AFM measurement showed RMS roughness of less than approximately 1 nanometer and crystal quality by XRD (002) FWHM of less than approximately 1500 arcsec. Such results indicate that the chlorine clean may be a significant reason for the improvements to the AlN film quality on 8 inch (111) silicon substrates.

A chlorine clean-based seasoning approach may also be used to improve fabrication of GaN, AlGaN, InGaN, or AlInGaN films with respect to high and repeatable crystal quality through manufacturing volumes. Perhaps most importantly, no cracking was observed in such films. A first layer of high crystal AlN film may contribute to the improved quality of such films. It is to be understood that the above film(s) growth is not restricted to 8 inch (111) silicon but may be applicable to any size of silicon substrate.

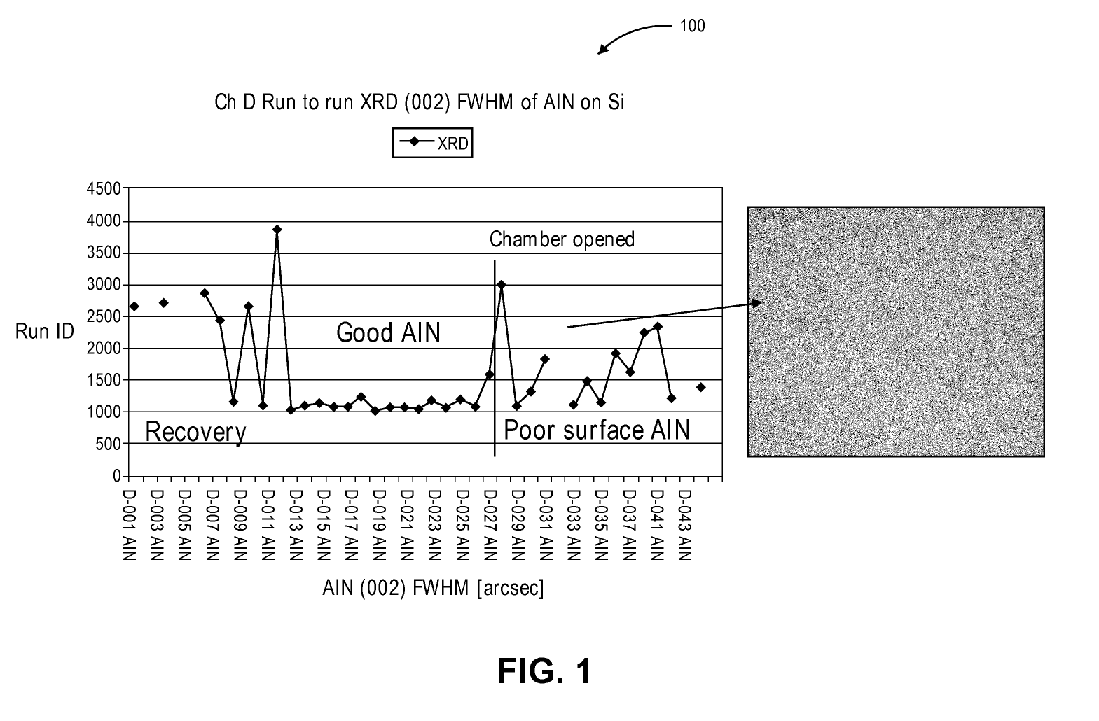

FIG. 1 includes a plot 100 of XRD data taken throughout a number of AlN deposition runs, in accordance with an embodiment of the present invention. Referring to plot 100, attempts were made to repeat the same AlN deposition recipe on 8 inch (111) silicon wafers. However, the AlN crystalline quality (as determined by XRD (0002) omega scan FWHM<2000 arcsec), is reduced following opening of the chamber. After recovery of an MOCVD chamber, good quality AlN layers are formed for a few runs. Specifically, following a preventative maintenance schedule, several runs of AlN+Cl2 cleans are required to recover the chamber for obtaining repeatable AlN layer crystal quality of FWHM<2000 arcsec. However, after opening the chamber, Ch D did not repeat the FWHM<2000 arcsec and smooth surface morphology with the same recipe. That is, the AlN layer nucleation on silicon was disturbed by the chamber opening, an otherwise non-standard procedure.

In an embodiment, the AlN deposition recipe includes stepped ramp up to minimize wafer non-uniform heating. In a specific example, trimethyl aluminum (TMAl) was used at a flow rate of approximately 1.9 sccm along with ammonia (NH₃) at a flow rate of approximately 2000 sccm. The pressure is approximately 40 Torr and the temperature is approximately 1100 degrees Celsius. In an embodiment, the clean recipe includes use of a clean and cycle purge power balance 12/22 (inner/middle), a gas load of approximately 75 SLM. A 6 cycle deposition and Cl₂ clean loop is used which includes a chlorine clean having a gas load of approximately 41 SLM, a pressure of approximately 100 Torr, a temperature of approximately 700 degrees Celsius. Of the gas load, chlorine (Cl₂) initially contributes approximately 2 SLM and is run for approximately 180 seconds. The Cl₂ delivery is ramped up to approximately 4 SLM for approximately 60 seconds, at a pressure of approximately 100 Torr, a temperature of approximately degrees Celsius. The remainder of the gas load may include nitrogen (N2). A process height for the dummy wafer deposition is, in an embodiment, approximately 10 millimeters.

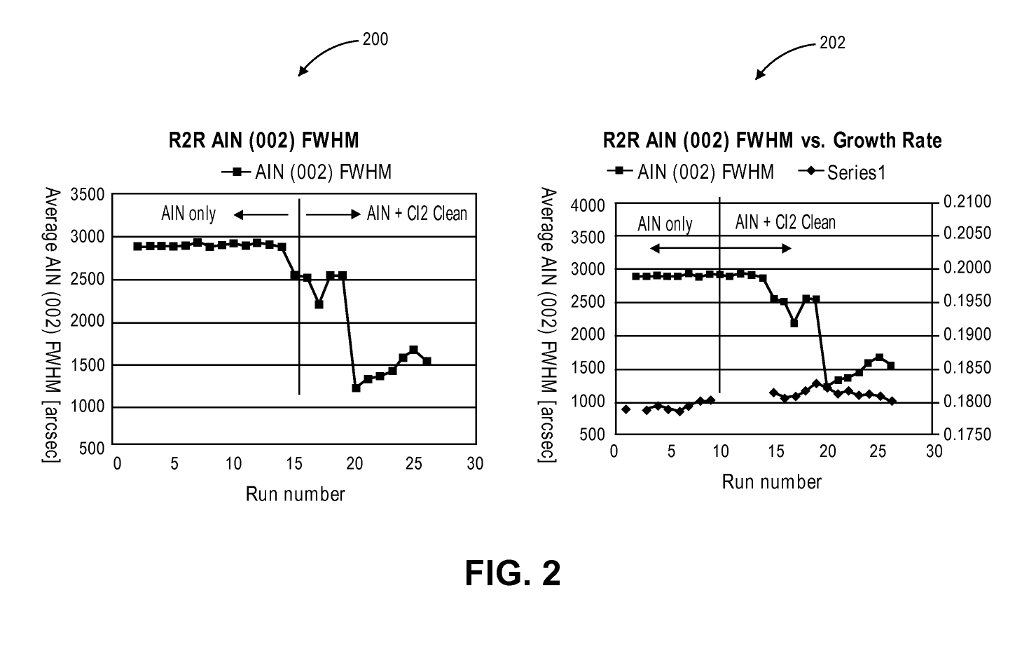

FIG. 2 includes AlN (002) FWHM plots 200 and 202 for AlN-only versus AlN and Cl₂ clean cycles, respectively, in accordance with an embodiment of the present invention. Referring to plot 200, following preventative maintenance scheduling, there is no XRD FWHM improvement following repeated AlN deposition runs without added Cl2 cycle cleans. However, referring to plot 202, following 4 cycles AlN deposition and Cl₂ clean, the surface morphology and crystal quality of a then deposited AlN layer exhibits marked improvement. Thus, the chlorine clean is at least somewhat responsible for AlN crystal quality improvement.

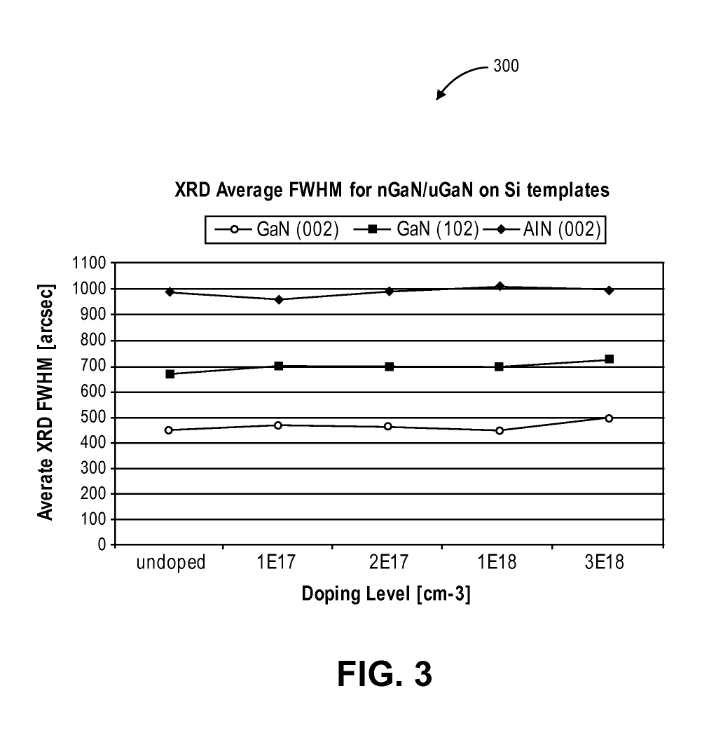

FIG. 3 is a plot 300 of XRD measurements of GaN (002), GaN (102), and AlN (002) films, in accordance with an embodiment of the present invention. Referring to plot 300, high quality n-doped GaN (nGaN) and un-doped GaN (uGaN) above 8 inch (111) silicon with an intervening AlN layer is achieved after AlN deposition/Cl₂ cleans plurality cycle seasoning of an MOCVD chamber. Following deposition of the AlN layer, the layers of uGaN and nGaN on AlN/Si are grown at high crystal quality as shown in plot 300. Furthermore, AlN AFM surface measurements taken after the seasoning indicating the surface RMS roughness is less than 1 nanometer.

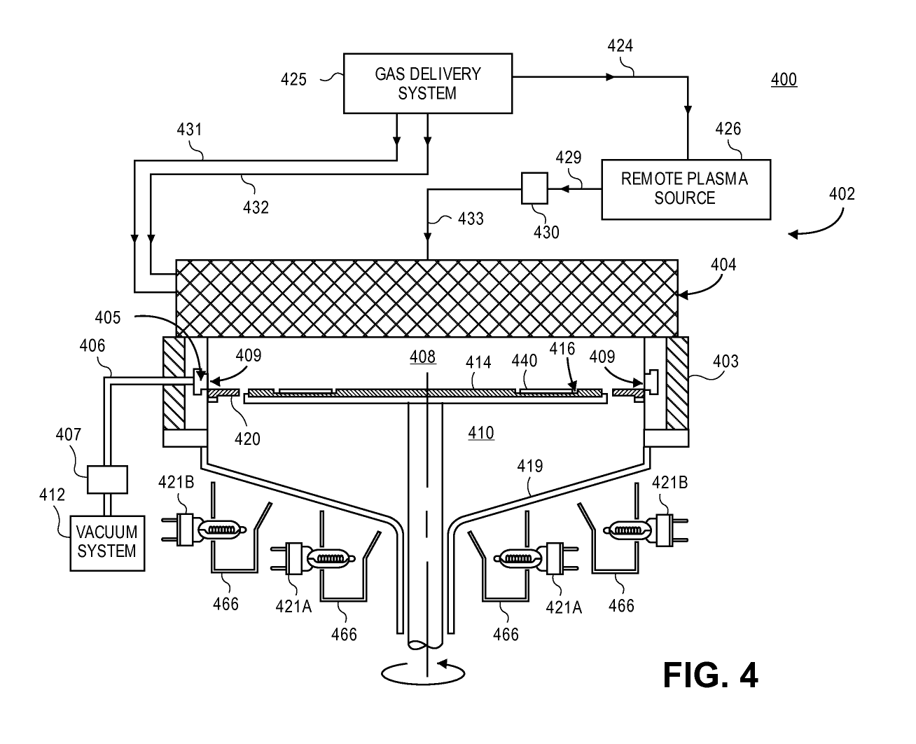

An example of an MOCVD chamber suitable for use in forming III-V materials using MOCVD with chlorine cleans operations, in accordance with embodiments of the present invention, is illustrated and described with respect to FIG. 4. FIG. 4 is a schematic cross-sectional view of an MOCVD chamber.

The apparatus 400 shown in FIG. 4 includes a chamber 402, a gas delivery system 425, a remote plasma source 426, and a vacuum system 412. The chamber 402 includes a chamber body 403 that encloses a processing volume 408. A showerhead assembly 404 is disposed at one end of the processing volume 408, and a substrate carrier 414 is disposed at the other end of the processing volume 408. A lower dome 419 is disposed at one end of a lower volume 410, and the substrate carrier 414 is disposed at the other end of the lower volume 410. The substrate carrier 414 is shown in process position, but may be moved to a lower position where, for example, the substrates 440 may be loaded or unloaded. An exhaust ring 420 may be disposed around the periphery of the substrate carrier 414 to help prevent deposition from occurring in the lower volume 410 and also help direct exhaust gases from the chamber 402 to exhaust ports 409. The lower dome 419 may be made of transparent material, such as high-purity quartz, to allow light to pass through for radiant heating of the substrates 440. The radiant heating may be provided by a plurality of inner lamps 421A and outer lamps 421B disposed below the lower dome 419, and reflectors 466 may be used to help control chamber 402 exposure to the radiant energy provided by inner and outer lamps 421A, 421B. Additional rings of lamps may also be used for finer temperature control of the substrate 440.

The substrate carrier 414 may include one or more recesses 416 within which one or more substrates 440 may be disposed during processing. The substrate carrier 414 may carry six or more substrates 440. In one embodiment, the substrate carrier 414 carries eight substrates 440. It is to be understood that more or less substrates 440 may be carried on the substrate carrier 414. Typical substrates 440 may include sapphire, silicon carbide (SiC), silicon, or gallium nitride (GaN). It is to be understood that other types of substrates 440, such as glass substrates 440, may be processed. Substrate 440 size may range from 50 mm-100 mm in diameter or larger. The substrate carrier 414 size may range from 200 mm-750 mm. The substrate carrier 414 may be formed from a variety of materials, including SiC or SiC-coated graphite. It is to be understood that substrates 440 of other sizes may be processed within the chamber 402 and according to the processes described herein. The showerhead assembly 404 may allow for more uniform deposition across a greater number of substrates 440 and/or larger substrates 440 than in traditional MOCVD chambers, thereby increasing throughput and reducing processing cost per substrate 440.

The substrate carrier 414 may rotate about an axis during processing. In one embodiment, the substrate carrier 414 may be rotated at about 2 RPM to about 100 RPM. In another embodiment, the substrate carrier 414 may be rotated at about 30 RPM. Rotating the substrate carrier 414 aids in providing uniform heating of the substrates 440 and uniform exposure of the processing gases to each substrate 440.

The plurality of inner and outer lamps 421A, 421B may be arranged in concentric circles or zones (not shown), and each lamp zone may be separately powered. In one embodiment, one or more temperature sensors, such as pyrometers (not shown), may be disposed within the showerhead assembly 404 to measure substrate 440 and substrate carrier 414 temperatures, and the temperature data may be sent to a controller (not shown) which can adjust power to separate lamp zones to maintain a predetermined temperature profile across the substrate carrier 414. In another embodiment, the power to separate lamp zones may be adjusted to compensate for precursor flow or precursor concentration non-uniformity. For example, if the precursor concentration is lower in a substrate carrier 414 region near an outer lamp zone, the power to the outer lamp zone may be adjusted to help compensate for the precursor depletion in this region.

The inner and outer lamps 421A, 421B may heat the substrates 440 to a temperature of about 400 degrees Celsius to about 1200 degrees Celsius. It is to be understood that the invention is not restricted to the use of arrays of inner and outer lamps 421A, 421B. Any suitable heating source may be utilized to ensure that the proper temperature is adequately applied to the chamber 402 and substrates 440 therein. For example, in another embodiment, the heating source may include resistive heating elements (not shown) which are in thermal contact with the substrate carrier 414.

A gas delivery system 425 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 402. Different gases, such as precursor gases, carrier gases, purge gases, cleaning/etching gases or others may be supplied from the gas delivery system 425 to separate supply lines 431, 432, and 433 to the showerhead assembly 404. The supply lines 431, 432, and 433 may include shut-off valves and mass flow controllers or other types of controllers to monitor and regulate or shut off the flow of gas in each line.

A conduit 429 may receive cleaning/etching gases from a remote plasma source 426. The remote plasma source 426 may receive gases from the gas delivery system 425 via supply line 424, and a valve 430 may be disposed between the showerhead assembly 404 and remote plasma source 426. The valve 430 may be opened to allow a cleaning and/or etching gas or plasma to flow into the showerhead assembly 404 via supply line 433 which may be adapted to function as a conduit for a plasma. In another embodiment, apparatus 400 may not include remote plasma source 426 and cleaning/etching gases may be delivered from gas delivery system 425 for non-plasma cleaning and/or etching using alternate supply line configurations to shower head assembly 404.

The remote plasma source 426 may be a radio frequency or microwave plasma source adapted for chamber 402 cleaning and/or substrate 440 etching. Cleaning and/or etching gas may be supplied to the remote plasma source 426 via supply line 424 to produce plasma species which may be sent via conduit 429 and supply line 433 for dispersion through showerhead assembly 404 into chamber 402. Gases for a cleaning application may include fluorine, chlorine or other reactive elements.

In another embodiment, the gas delivery system 425 and remote plasma source 426 may be suitably adapted so that precursor gases may be supplied to the remote plasma source 426 to produce plasma species which may be sent through showerhead assembly 404 to deposit CVD layers, such as Group III-V films, for example, on substrates 440. In general, a plasma, which is a state of matter, is created by the delivery of electrical energy or electromagnetic waves (e.g., radio frequency waves, microwaves) to a process gas (e.g., precursor gases) to cause it to at least partially breakdown to form plasma species, such as ions, electrons and neutral particles (e.g., radicals). In one example, a plasma is created in an internal region of the plasma source 426 by the delivery electromagnetic energy at frequencies less than about 100 gigahertz (GHz). In another example, the plasma source 426 is configured to deliver electromagnetic energy at a frequency between about 0.4 kilohertz (kHz) and about 200 megahertz (MHz), such as a frequency of about 162 megahertz (MHz), at a power level less than about 4 kilowatts (kW). It is believed that the formed plasma enhances the formation and activity of the precursor gas(es) so that the activated gases, which reach the surface of the substrate(s) during the deposition process can rapidly react to form a layer that has improved physical and electrical properties.

A purge gas (e.g., nitrogen) may be delivered into the chamber 402 from the showerhead assembly 404 and/or from inlet ports or tubes (not shown) disposed below the substrate carrier 414 and near the bottom of the chamber body 403. The purge gas enters the lower volume 410 of the chamber 402 and flows upwards past the substrate carrier 414 and exhaust ring 420 and into multiple exhaust ports 409 which are disposed around an annular exhaust channel 405. An exhaust conduit 406 connects the annular exhaust channel 405 to a vacuum system 412 which includes a vacuum pump (not shown). The chamber 402 pressure may be controlled using a valve system 407 which controls the rate at which the exhaust gases are drawn from the annular exhaust channel 405.

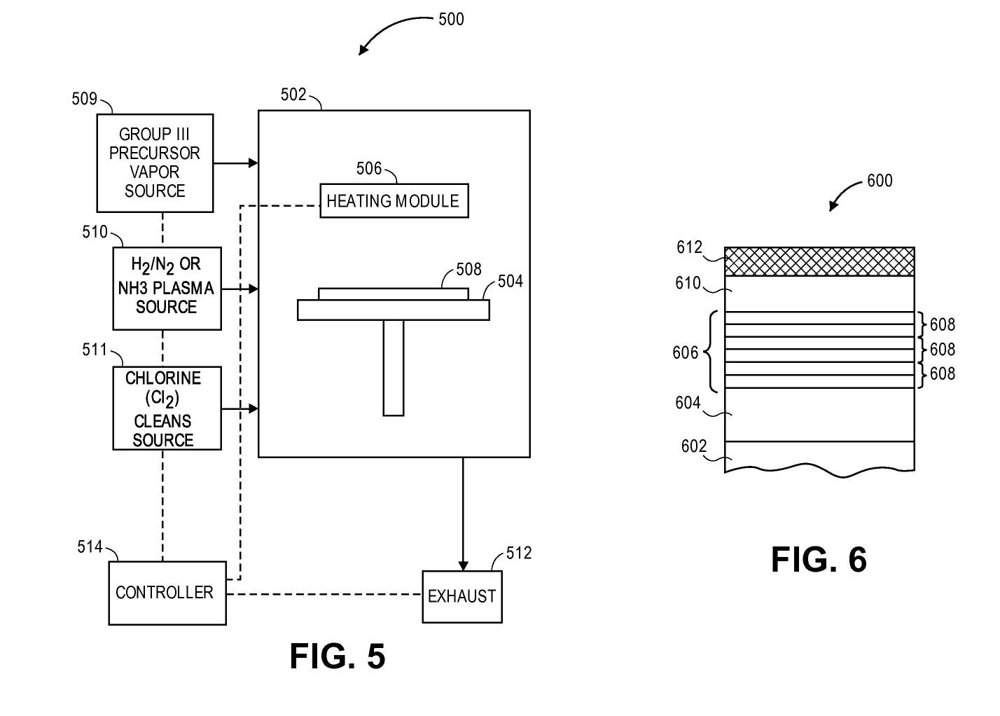

FIG. 5 illustrates a system suitable for use in forming III-V materials using MOCVD with chlorine cleans operations, in accordance with an embodiment of the present invention.

Referring to FIG. 5, the system 500 may include a deposition chamber 502 that includes a substrate support 504 and a heating module 506. The substrate support 504 may be adapted to support a substrate 508 during film formation within the chamber 502, and the heating module 506 may be adapted to heat the substrate 508 during film formation within the deposition chamber 502. More than one heating module, and/or other heating module locations may be used. The heating module 506 may include, for example, a lamp array or any other suitable heating source and/or element.

The system 500 may also include a group III, e.g., gallium, vapor source 509, a N₂/H₂ or NH₃ plasma source 510, a chlorine (Cl2) cleans source 511, and an exhaust system 512 coupled to the deposition chamber 502. The system 500 may also include a controller 514 coupled to the deposition chamber 502, the group III vapor source 509, the N₂/H₂ or NH₃ plasma source 510, the chlorine (Cl2) cleans source 511, and/or the exhaust system 512. The exhaust system 512 may include any suitable system for exhausting waste gasses, reaction products, or the like from the chamber 502, and may include one or more vacuum pumps. The N₂/H₂ or NH₃ plasma source 510 may be used for reaction with vapor for the group III vapor source 509. The N₂/H₂ or NH₃ plasma source 510 may be used to generate a plasma in the deposition chamber or remotely and introduced into the deposition chamber.

The controller 514 may include one or more microprocessors and/or microcontrollers, dedicated hardware, a combination the same, etc., that may be employed to control operation of the deposition chamber 502, the group III vapor source 509, the N₂/H₂ or NH₃ plasma source 510, the chlorine (Cl2) cleans source 511, and/or the exhaust system 512. In at least one embodiment, the controller 514 may be adapted to employ computer program code for controlling operation of the system 500. For example, the controller 514 may perform or otherwise initiate one or more of the operations of any of the methods/processes described herein. Any computer program code that performs and/or initiates such operations may be embodied as a computer program product. Each computer program product described herein may be carried by a medium readable by a computer (e.g., a floppy disc, a compact disc, a DVD, a hard drive, a random access memory, etc.).

Group III precursor vapor may be created by placing an elemental group III species into a vessel, such as a crucible, and heating the vessel to melt the elemental group III species. The vessel may be heated to a temperature of from about 100 degrees Celsius to about 250 degrees Celsius. In some embodiments, nitrogen gas may be passed over the vessel containing the molten elemental group III species at a pressure of about 1 Torr and pumped to the process chamber. The nitrogen may be flowed at a rate of about 200 standard cubic centimeters per minute (sccm). The group III precursor vapor may be drawn into the process chamber by a vacuum. In an alternative embodiment, the substrate may be exposed to the group III precursor vapor, the N₂/H₂ or NH₃ based plasma and one or more of hydrogen and hydrogen chloride. The hydrogen and/or the hydrogen chloride may increase the rate of deposition. In another embodiment of the present invention, a group III-nitride film may be deposited on a substrate using a group III sesquichloride precursor and/or a group III hydride precursor.

As an example of a portion of a III-V material-based LED contemplated for illustrative purposes herein, FIG. 6 illustrates a cross-sectional view of a gallium nitride (GaN)-based LED, in accordance with an embodiment of the present invention. Referring to FIG. 6, a GaN-based LED 600 includes an n-type GaN template 604 (e.g., n-type GaN, n-type InGaN, n-type AlGaN, n-type InAlGaN) on a substrate 602 (e.g., planar sapphire substrate, patterned sapphire substrate (PSS), silicon substrate, silicon carbide substrate). The GaN-based LED 600 also includes a multiple quantum well (MQW), or active region, structure or film stack 606 on or above the n-type GaN template 604 (e.g., an MQW composed of one or a plurality of field pairs of InGaN well/GaN barrier material layers 608, as depicted in FIG. 6). The GaN-based LED 600 also includes a p-type GaN (p-GaN) layer or film stack 610 on or above the MQW 606, and a metal contact or ITO layer 612 on the p-GaN layer.

It is to be understood that one or more of the above processes may be performed in a dedicated chamber within a cluster tool, or other tool with more than one chamber, e.g. an in-line tool arranged to have a dedicated chamber for fabricating layers of an LED. It is also to be understood that embodiments of the present invention need not be limited to the fabrication of LEDs. For example, in another embodiment, devices other than LED devices may be fabricated by an MOCVD process using a chlorine cleans operation, such as but not limited to field-effect transistor (FET) devices or power devices. In such embodiments, there may not be a need for a p-type material on top of a structure of layers. Instead, an n-type or un-doped material may be used in place of the p-type layer.

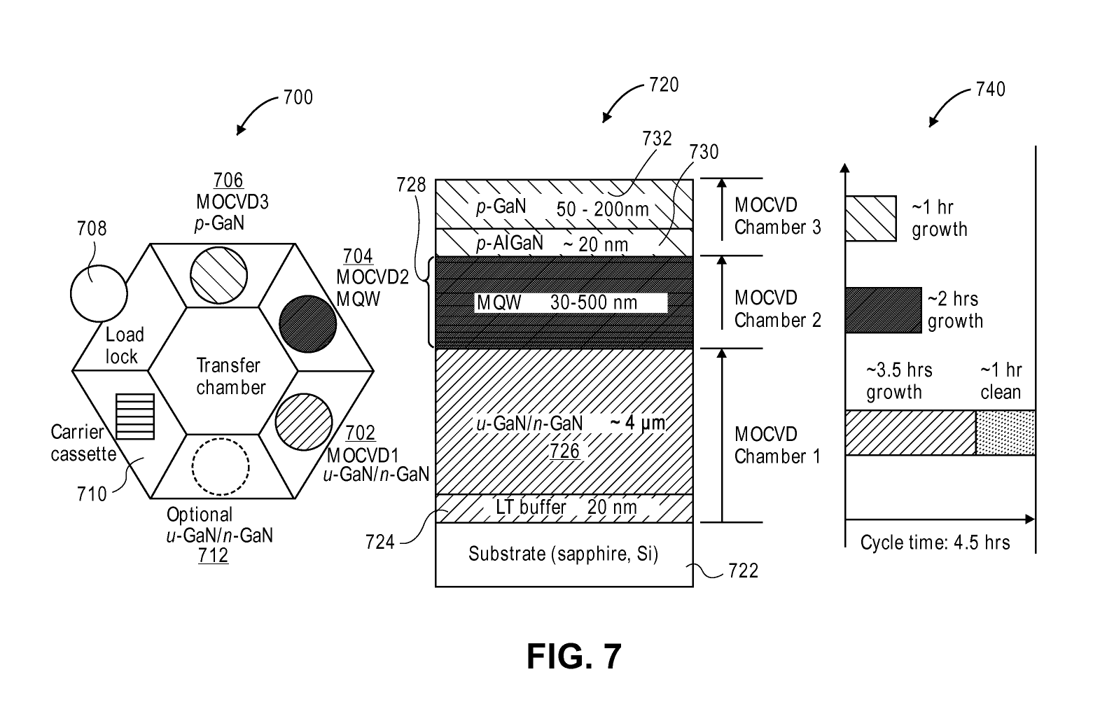

As an example of a multiple chamber system and process performed therein, FIG. 7 illustrates a cluster tool schematic, an LED structure, and a time-to-deposition plot, in accordance with one or more embodiments of the present invention.

Referring to FIG. 7, a cluster tool 700 includes an un-doped and/or n-type gallium nitride MOCVD reaction chamber 702 (MOCVD1: u-GaN/n-GaN), a multiple quantum well (MQW) MOCVD reaction chamber 704 (MOCVD2: MQW), and a p-type gallium nitride MOCVD reaction chamber 706 (MOCVD3: p-GaN). The cluster tool 700 may also include a load lock 708, a carrier cassette 710, and an optional additional un-doped and/or n-type gallium nitride MOCVD reaction chamber 712 for high volume applications, all of which are depicted in FIG. 7.

An LED structure 720 includes a stack of various material layers, many of which include III-V materials. For example, the LED structure 720 includes a silicon or sapphire substrate 722 (Substrate: sapphire, Si), a 20 nanometer thick buffer layer 724 (LT buffer), and an approximately 4 microns thick un-doped/n-type gallium nitride combination layer 726 (u-GaN/n-GaN). The buffer layer 724 may be a gallium nitride layer formed at relatively low processing temperatures. The buffer layer 724 and the un-doped/n-type gallium nitride combination layer 726 are formed in un-doped and/or n-type gallium nitride MOCVD reaction chamber 702 of cluster tool 700. The LED structure 720 also includes an MQW structure 728 with a thickness in the range of 30-500 nanometers. The MQW structure 728 is formed in MQW MOCVD reaction chamber 704 of cluster tool 700. The LED structure 720 also includes an approximately 20 nanometers thick p-type gallium aluminum nitride layer 730 (p-AlGaN) and a p-type gallium nitride layer 732 with a thickness in the range of 50-200 nanometers (p-GaN). The p-type gallium aluminum nitride layer 730 and the p-type gallium nitride layer 732 are formed in p-type gallium nitride MOCVD reaction chamber 706 of cluster tool 700.

A time-to-deposition plot 740 represents an example of chamber usage in cluster tool 700. The formation of the MQW structure 728 in MQW MOCVD reaction chamber 704 has a growth time of approximately 2 hours. And, the formation of the p-type gallium aluminum nitride layer 730 and the p-type gallium nitride layer 732 in p-type gallium nitride MOCVD reaction chamber 706 has a growth time of approximately 1 hour. Meanwhile, the formation of the buffer layer 724 and the un-doped/n-type gallium nitride combination layer 726 in un-doped and/or n-type gallium nitride MOCVD reaction chamber 702 has a growth time of approximately 3.5 hours. An additional approximately 1 hour may be required for chamber cleaning of chamber 702. Thus, overall, the cycle time for fabricating LED structure 720 in cluster tool 700 may be dictated by the cycle time of un-doped and/or n-type gallium nitride MOCVD reaction chamber 702, which is approximately 4.5 hours. It is to be understood that cleaning time may, but need not, include time for shut-down, plus clean time, plus recovery time. It is also to be understood that the above may represent an average since cleaning may not be performed between every chamber usage.

A timing sequence for LED material deposition specific to the formation of the buffer layer 724 and the un-doped/n-type gallium nitride combination layer 726 in un-doped and/or n-type gallium nitride MOCVD reaction chamber 702, as described in association with FIG. 7, is provided below. For example, the growth time of approximately 3.5 hours is broken into a 10 minute high temperature treatment of a sapphire substrate, a 5 minute low temperature formation of a buffer layer, a 10 minute buffer annealing operation, a 30 minute growth recovery operation, a 2 hour un-doped/n-type gallium nitride combination layer formation operation, and a 30 minute temperature ramp and stabilization operation (e.g., temp ramp 2-3° C./s).

It is to be understood that embodiments of the present invention are not limited to formation of layers on silicon substrates. Other embodiments may include the use of any suitable non-patterned or patterned single crystalline substrate upon which a group III-nitride epitaxial film may be formed. The substrate may be formed from a substrate, such as but not limited to a sapphire (Al₂O₃) substrate, a silicon carbide (SiC) substrate, a silicon on diamond (SOD) substrate, a quartz (SiO₂) substrate, a glass substrate, a zinc oxide (ZnO) substrate, a magnesium oxide (MgO) substrate, and a lithium aluminum oxide (LiAlO₂) substrate. Any well know method, such as masking and etching may be utilized to form features, such as posts, from a planar substrate to create a patterned substrate. In a specific embodiment, however, the patterned substrate is a (0001) patterned sapphire substrate (PSS). Patterned sapphire substrates may be ideal for use in the manufacturing of LEDs because they increase the light extraction efficiency which is extremely useful in the fabrication of a new generation of solid state lighting devices. Other embodiments include the use of planar (non-patterned) substrates, such as a planar sapphire substrate. In other embodiments, the approaches herein are used to provide a group III-V material layer directly on a silicon substrate.

In some embodiments, growth of a gallium nitride or related film on a substrate is performed along a (0001) Ga-polarity, N-polarity, or non-polar a-plane {112-0} or m-plane {101-0}, or semi-polar planes. In some embodiments, posts formed in a patterned growth substrate are round, triangular, hexagonal, rhombus shape, or other shapes effective for block-style growth. In an embodiment, the patterned substrate contains a plurality of features (e.g., posts) having a cone shape. In a particular embodiment, the feature has a conical portion and a base portion. In an embodiment of the present invention, the feature has a tip portion with a sharp point to prevent over growth. In an embodiment, the tip has an angle (θ) of less than 145° and ideally less than 110°. Additionally, in an embodiment, the feature has a base portion which forms a substantially 90° angle with respect to the xy plane of the substrate. In an embodiment of the present invention, the feature has a height greater than one micron and ideally greater than 1.5 microns. In an embodiment, the feature has a diameter of approximately 3.0 microns. In an embodiment, the feature has a diameter height ratio of approximately less than 3 and ideally less than 2. In an embodiment, the features (e.g., posts) within a discrete block of features (e.g., within a block of posts) are spaced apart by a spacing of less than 1 micron and typically between 0.7 to 0.8 microns.

It is also to be understood that embodiments of the present invention need not be limited to n-GaN as a group III-V layer formed on a patterned substrate, such as described in association with FIG. 6. For example, other embodiments may include any group III-nitride epitaxial film that can be suitably deposited by MOCVD, or the like, in conjunction with a chlorine cleans process. The group III-nitride film may be a binary, ternary, or quaternary compound semiconductor film formed from a group III element or elements selected from gallium, indium and aluminum and nitrogen. That is, the group III-nitride crystalline film can be any solid solution or alloy of one or more Group III element and nitrogen, such as but not limited to GaN, AlN, InN, AlGaN, InGaN, InAlN, and InGaAlN.

However, in a specific embodiment, the group III-nitride film is an n-type gallium nitride (GaN) film. The Group III-Nitride film can have a thickness between 2-500 microns and is typically formed between 2-15 microns. In an embodiment of the present invention, the group III-nitride film has a thickness of at least 3.0 microns to sufficiently suppress threading dislocations. Additionally, the group III-nitride film can be doped. The group III-nitride film can be p-typed doped using a p-type dopant such as but not limited Mg, Be, Ca, Sr, or any Group I or Group II element have two valence electrons. The group III-nitride film can be p-type doped to a conductivity level of between 1×10¹⁶ to 1×10²⁰ atoms/cm³. The group III-nitride film can be n-type doped using an n-type dopant such as but not limited to, Si, Ge, Sn, Pb, or a suitable Group IV, Group V, or Group VI element. The group III-nitride film can be n-type doped to a conductivity level of between 1×10¹⁶ to 1×10²⁰ atoms/cm³.

Thus, LEDs and related devices may be fabricated from layers of, e.g., group III-V films, especially group III-nitride films. As described above, some embodiments of the present invention relate to forming gallium nitride (GaN) layers in a dedicated chamber of a fabrication tool, such as in a dedicated metal-organic chemical vapor deposition (MOCVD) chamber. In some embodiments of the present invention, GaN is a binary GaN film, but in other embodiments, GaN is a ternary film (e.g., InGaN, AlGaN) or is a quaternary film (e.g., InAlGaN). In at least some embodiments, the group III-nitride material layers are formed epitaxially. They may be formed directly on a substrate or on a buffers layer disposed on a substrate, such as on a silicon substrate.

Thus, methods of forming III-V materials using MOCVD with chlorine cleans operations have been disclosed. A chlorine-clean operation may further season an MOCVD process for improved throughput for high volume manufacturing.

What is claimed is:

1. A method of fabricating a III-V material layer, the method comprising:
cleaning a metal organic chemical vapor deposition (MOCVD) chamber with a chlorine-clean process; and, subsequently,
moving a silicon substrate into the MOCVD chamber; and
forming, in the MOCVD chamber, a gallium nitride (GaN) layer directly on the silicon substrate.

2. The method of claim 1, wherein cleaning the MOCVD chamber with the chlorine-clean process comprises flowing chlorine (Cl₂) gas into the MOCVD chamber.

3. The method of claim 1, wherein forming the GaN layer comprises performing an MOCVD process approximately 13 millimeters from a showerhead of the MOCVD chamber.

4. The method of claim 3, wherein performing the MOCVD process comprises using a pressure in the MOCVD chamber of less than approximately 100 Torr.

5. The method of claim 4, performing the MOCVD process further comprises using a temperature in the MOCVD chamber of greater than approximately 1020 degrees Celsius.

6. The method of claim 1, further comprising:
subsequent to moving the silicon substrate into the MOCVD chamber and prior to forming the GaN layer, performing a hydrogen (H₂) bake of the silicon substrate.

7. The method of claim 1, wherein cleaning the MOCVD chamber with the chlorine-clean process further comprises cleaning a substrate carrier.

8. The method of claim 7, cleaning the substrate carrier comprises exposing the substrate carrier to chlorine (Cl₂) gas at a distance of approximately 25 millimeters from a showerhead of the MOCVD chamber.

9. The method of claim 8, wherein the substrate carrier is maintained at a temperature of greater than or equal to approximately 700 degrees Celsius.

10. The method of claim 9, wherein a surface of the showerhead is maintained at a temperature of greater than or equal to approximately 150 degrees Celsius.

11. A method of fabricating a III-V material layer, the method comprising:
cleaning a metal organic chemical vapor deposition (MOCVD) chamber with a plurality of chlorine-clean cycles; and, subsequently,
moving a silicon substrate into the MOCVD chamber; and
forming, in the MOCVD chamber, an aluminum nitride (AlN) layer directly on the silicon substrate.

12. The method of claim 11, wherein cleaning the MOCVD chamber with the plurality of chlorine-clean cycles comprises flowing chlorine (Cl₂) gas into the MOCVD chamber during one or more of the chlorine-clean cycles.

13. The method of claim 11, wherein cleaning the MOCVD chamber with the plurality of chlorine-clean cycles comprises using a number of chlorine-clean cycles approximately in the range of 2-6.

14. The method of claim 11, further comprising:
forming a dummy aluminum nitride (AlN) layer on a dummy substrate with a plurality of deposition cycles intertwined with the plurality of chlorine-clean cycles.

15. The method of claim 14, wherein cleaning the MOCVD chamber and forming the dummy AlN layer is used for seasoning the MOCVD chamber prior to forming the AlN layer directly on the silicon substrate.

16. The method of claim 15, wherein seasoning, the MOCVD chamber comprises forming residual chlorine or chloride species in the MOCVD chamber, one of the chloride species comprising aluminum chloride (AlCl₃).

17. The method of claim 11, further comprising:
subsequent to moving the silicon substrate into the MOCVD chamber and prior to forming the AlN layer, performing a hydrogen (H₂) bake of the silicon substrate.

18. The method of claim 11, wherein cleaning the MOCVD chamber with the plurality of chlorine-clean cycles comprises marinating a pressure of approximately 100 Torr and a temperature of approximately 700 degrees Celsius in the MOCVD chamber during one or more of the chlorine-clean cycles.

19. The method of claim 11, wherein forming the AlN layer comprises flowing trimethyl aluminum (TMAl) and ammonia (NH₃) into the MOCVD chamber.

20. The method of claim 19, wherein flowing TMAl and NH₃ into the MOCVD chamber comprises using, in the MOCVD chamber, a pressure of approximately 40 Torr and a temperature of approximately 1100 degrees Celsius.
